(19) United States
(12) Patent Application Publication
(10) Pub. No.: US 2016/0295690 A1
(43) Pub. Date: Oct. 6, 2016

(54) SEMICONDUCTOR DEVICE

(71) Applicant: Fuji Electric Co., Ltd., Kanagawa (JP)

(72) Inventor: Sho TAKANO, Tokyo (JP)

(73) Assignee: Fuji Electric Co., Ltd., Kanagawa (JP)

(21) Appl. No.: 15/063,132

(22) Filed: Mar. 7, 2016

(30) Foreign Application Priority Data
Apr. 2, 2015 (JP) 2015-075730

(51) Int. Cl. H05K 1/02; H05K 1/18; H02M 7/00

(52) U.S. Cl. CPC H05K 1/0296; H02M 7/003; H05K 1/181; H05K 1/0298

(57) ABSTRACT

A semiconductor device includes: a plurality of semiconductor units each including a semiconductor element and a plurality of main terminals that are electrically connected to the semiconductor element, the plurality of semiconductor units being arranged in a same plane with a same orientation in a plan view; and a connecting unit that electrically connects in parallel the semiconductor units arranged in substantially the same plane, the connecting unit having a plurality of external terminals that are respectively connected to the main terminals of each of the semiconductor units, wherein a geometrical arrangement of the main terminals, in a plan view, of each of the semiconductor units relative to an overall plan-view shape of the semiconductor unit and a geometrical arrangement of the external terminals, in a plan view, of the connecting unit relative to an overall plan-view shape of the connecting unit have a substantial geometrical similarity with each other.

### BACKGROUND OF THE INVENTION

1. Technical Field

The present invention relates to a semiconductor device.

2. Background Art

High-efficiency, low-noise power converters have been developed for use in solar power generation power conditioners, electric automobile motor controllers, and the like. Power converters are configured using inverters, and these inverters are configured using semiconductor devices known as power semiconductor modules. Power semiconductor modules include semiconductor chips in which semiconductor elements such as insulated-gate bipolar transistors (IGBT) or freewheeling diodes (FWD) are formed. Using a plurality of low current capacity semiconductor units in combination makes it possible to provide a power semiconductor module that exhibits high current capacity and the like (see Patent Document 1, for example).

Patent Document 1 describes a configuration in which the main terminals of a plurality of semiconductor units are arranged vertically in a line and connected together in parallel using bus bars on which external terminals are formed. These external terminals are exposed on the top surface of a power semiconductor module case and arranged in a line in the horizontal direction.

### RELATED ART DOCUMENT

### Patent Document

Patent Document 1: Japanese Patent Application Laid-Open Publication No. 2014-236150

### SUMMARY OF THE INVENTION

However, in the technology disclosed in Patent Document 1, the lengths of the wires from the main terminals of each semiconductor unit to the external terminals vary significantly for each bus bar, thereby causing variations between the currents that flow through those wires. As a result, each of the semiconductor units has a different inductance and electrical resistance. Therefore, the semiconductor units exhibit non-uniform heat generation during operation, and the current rating may be exceeded in some locations.

The present invention was made in view of these problems and aims to provide a semiconductor device in which the variation between currents flowing from the main terminals to the external terminals is reduced. Accordingly, the present invention is directed to a scheme that substantially obviates one or more of the problems due to limitations and disadvantages of the related art.

Additional or separate features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

To achieve these and other advantages and in accordance with the purpose of the present invention, as embodied and broadly described, in one aspect, the present disclosure provides a semiconductor device, including: a plurality of semiconductor units each including a semiconductor element and a plurality of main terminals that are electrically connected to the semiconductor element, the plurality of semiconductor units being arranged in a same plane with a same orientation in a plan view; and a connecting unit that electrically connects in parallel the semiconductor units arranged in substantially the same plane, the connecting unit having a plurality of external terminals that are respectively connected to the main terminals of each of the semiconductor units, wherein a geometrical arrangement of the main terminals, in a plan view, of each of the semiconductor units relative to an overall plan-view shape of the semiconductor unit and a geometrical arrangement of the external terminals, in a plan view, of the connecting unit relative to an overall plan-view shape of the connecting unit have a substantial geometrical similarity with each other.

The semiconductor device configured as described above reduces variation between currents and has improved electrical properties.

It is to be understood that both the foregoing general description and the following detailed description are exemplary and explanatory, and are intended to provide further explanation of the invention as claimed.

### BRIEF DESCRIPTION OF THE DRAWINGS

FIGS. 1A and 1B illustrate a semiconductor unit according to Embodiment 1.

FIG. 2 is a top view of a multilayer substrate of the semiconductor unit according to Embodiment 1.

FIG. 3 is a top view of a printed circuit board of the semiconductor unit according to Embodiment 1.

FIG. 4 is a circuit diagram illustrating a circuit configuration of the semiconductor unit according to Embodiment 1.

FIGS. 5A and 5B illustrate a semiconductor device configured using a plurality of the semiconductor units according to Embodiment 1.

FIG. 6 illustrates the details of the semiconductor unit according to Embodiment 1.

FIGS. 7A and 7B illustrate the details of the semiconductor unit according to Embodiment 1.

FIG. 8 illustrates a reference example of a semiconductor device.

FIGS. 9A and 9B include graphs showing the characteristics of the semiconductor device according to Embodiment 1.

FIGS. 10A and 10B illustrate various ways of arranging a plurality of the semiconductor units according to Embodiment 1.

FIG. 11 is an exterior perspective view of a semiconductor unit according to Embodiment 2.

FIG. 12 is a circuit diagram illustrating a circuit configuration of the semiconductor unit according to Embodiment 2.

FIGS. 13A and 13B illustrate a semiconductor device according to Embodiment 2.

FIG. 14 is a top view of a first circuit layer of the connecting unit of the semiconductor device according to Embodiment 2.

FIG. 15 is a top view of a second circuit layer of the connecting unit of the semiconductor device according to Embodiment 2.

FIG. 16 is a top view of a third circuit layer of the connecting unit of the semiconductor device according to Embodiment 2.

### DETAILED DESCRIPTION OF EMBODIMENTS

Next, embodiments of the present invention will be described in detail with reference to figures.

### Embodiment 1

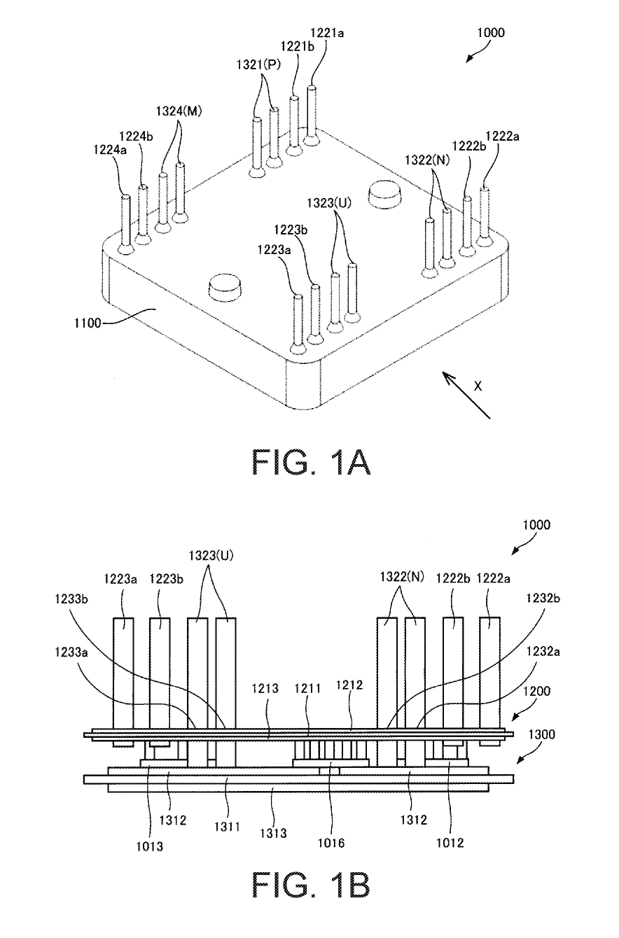

First, a semiconductor unit according to Embodiment 1 will be described with reference to FIGS. 1A and 1B.

FIGS. 1A and 1B illustrate the semiconductor unit according to Embodiment 1.

FIG. 1A is an exterior perspective view of the semiconductor unit 1000. FIG. 1B is a side view of the semiconductor unit 1000 when not sealed by a resin 1100 and as viewed from the X direction in FIG. 1A.

As illustrated in FIG. 1A, the semiconductor unit 1000 is molded into shape using a resin 1100 such as a thermosetting resin. The semiconductor unit 1000 includes main terminals 1321, 1322, 1323, and 1324, which are exposed extending in the same direction. Here, the main terminal 1321 is a P-terminal, the main terminal 1322 is an N-terminal, the main terminal 1323 is a U-terminal that outputs to a load, and the main terminal 1324 is an M-terminal that gives the midpoint potential between the P-terminal and the N-terminal. In Embodiment 1, each of the main terminals 1321 to 1324 includes two leads. However, this is only to increase the amount of current that flows to the main terminals, and both leads of each main terminal have the same function. In other words, the main terminals 1321 to 1324 do not necessarily need to include two leads, and each main terminal may include only a single lead. Therefore, the following description of the semiconductor unit 1000 according to Embodiment 1 assumes that each of the main terminals 1321 to 1324 is a single-lead terminal.

The semiconductor unit 1000 also includes control terminals 1221a, 1221b, 1222a, 1222b, 1223a, 1223b, 1224a, and 1224b, which are exposed extending in the same direction as the main terminals. The control terminals 1221a to 1224a function as gate terminals, and the control terminals 1221b to 1224b function as auxiliary source terminals.

FIG. 1A depicts a case in which the semiconductor unit 1000 is molded into shape using the resin 1100. However, the semiconductor unit 1000 may be provided as a stand-alone component and does not necessarily need to be molded into shape using the resin 1100. For example, all of the component parts may be electrically and mechanically connected as necessary and then sealed using a silicone gel or the like, as in conventional power semiconductor modules. However, using the resin 1100 to form a molded shape improves breakdown voltage properties and properties such as the ability to withstand power cycling and heat cycling in comparison with the sealed configuration that uses a silicone gel or the like. Furthermore, resin-molding the semiconductor unit 1000 prevents damage or the like due to foreign materials entering the interior, thereby facilitating handling when assembling together a plurality of the semiconductor units 1000.

As illustrated in FIG. 1B, the resin 1100 of the semiconductor unit 1000 seals in a printed circuit board 1200 and a multilayer substrate 1300 arranged facing the printed circuit board 1200.

The printed circuit board 1200 includes a resin layer 1211 and circuit layers 1212 and 1213 arranged on the front and rear surfaces of the resin layer 1211, respectively. Moreover, the control terminals 1221a to 1224a and 1221b to 1224b are fixed to the circuit layer 1212. The printed circuit board 1200 will be described in more detail later.

The multilayer substrate 1300 includes an insulating plate 1311, a plurality of circuit boards 1312 arranged on the front surface of the insulating plate 1311, and a metal plate 1313 arranged on the rear surface of the insulating plate 1311. Moreover, the main terminals 1321 to 1324 are fixed to the top surfaces of the circuit boards 1312. The main terminals 1321 to 1324 extend through through-holes 1232 and 1233 in the printed circuit board 1200 and protrude upwards.

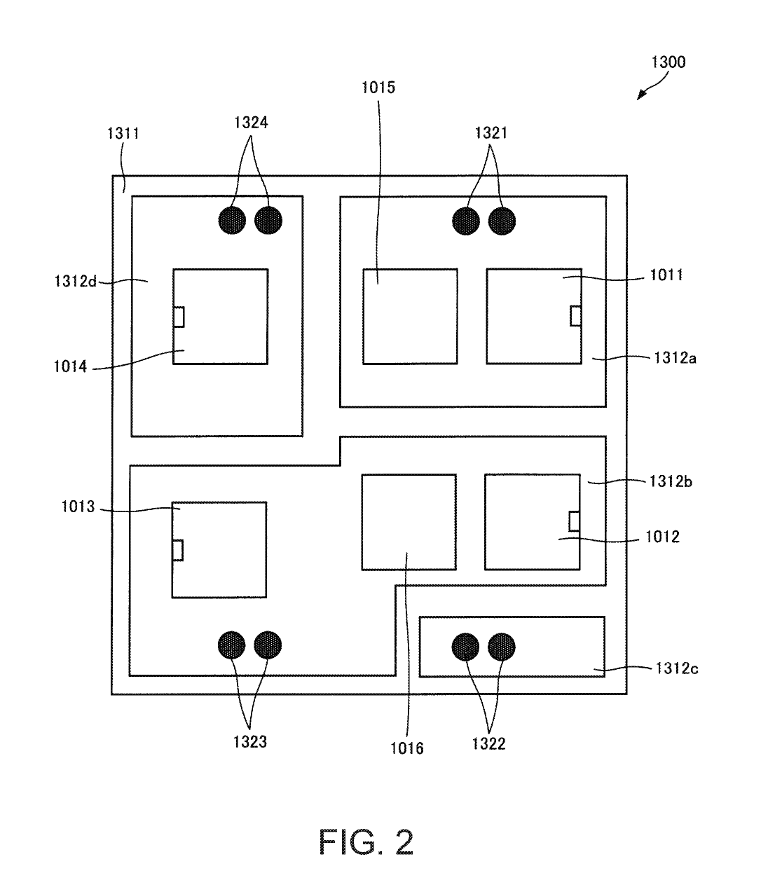

FIG. 2 is a top view of the multilayer substrate of the semiconductor unit according to Embodiment 1.

The multilayer substrate 1300 includes the insulating plate 1311 made from a ceramic material or the like and circuit boards 1312a to 1312d arranged on the main surface (the front surface) of the insulating plate 1311.

The circuit boards 1312a to 1312d are made from a conductive material such as copper. The circuit boards 1312a to 1312d are arranged on the main surface of the insulating plate 1311 and are electrically insulated from one another. A direct bonded copper (DBC) substrate or an active metal brazed (AMB) substrate may be used for the multilayer substrate 1300, for example.

IGBT semiconductor elements 1011 and 1012 are arranged on the circuit boards 1312a and 1312b. Furthermore, reverse-blocking IGBT semiconductor elements 1013 and 1014 are arranged on the circuit boards 1312b and 1312d. The collector electrodes on the rear surfaces of the semiconductor elements 1011 to 1014 are electrically connected to the circuit boards 1312a, 1312b, and 1312d using a conductive bonding material.

Schottky barrier diodes (SBD) 1015 and 1016 are arranged on the circuit boards 1312a and 1312b. The cathode electrodes on the rear surfaces of the diodes 1015 and 1016 are electrically connected to the circuit boards 1312a and 1312b using a conductive bonding material.

Furthermore, the main terminal 1321 is electrically connected to the circuit board 1312a using a conductive bonding material. Therefore, the main terminal 1321 is electrically connected to the collector electrode of the semiconductor element 1011 and to the cathode electrode of the diode 1015 via the circuit board 1312a.

The main terminal 1322 is electrically connected to the circuit board 1312c using a conductive bonding material.

The main terminal 1323 is electrically connected to the circuit board 1312b using a conductive bonding material. Therefore, the main terminal 1323 is electrically connected to the collector electrodes of the semiconductor elements 1012 and 1013 and to the cathode electrode of the diode 1016 via the circuit board 1312b.

The main terminal 1324 is electrically connected to the circuit board 1312d using a conductive bonding material. Therefore, the main terminal 1324 is electrically connected to the collector electrode of the semiconductor element 1014 via the circuit board 1312d.

In the semiconductor unit 1000, the multilayer substrate 1300 is connected to the printed circuit board 1200 using a plurality of conductive posts.

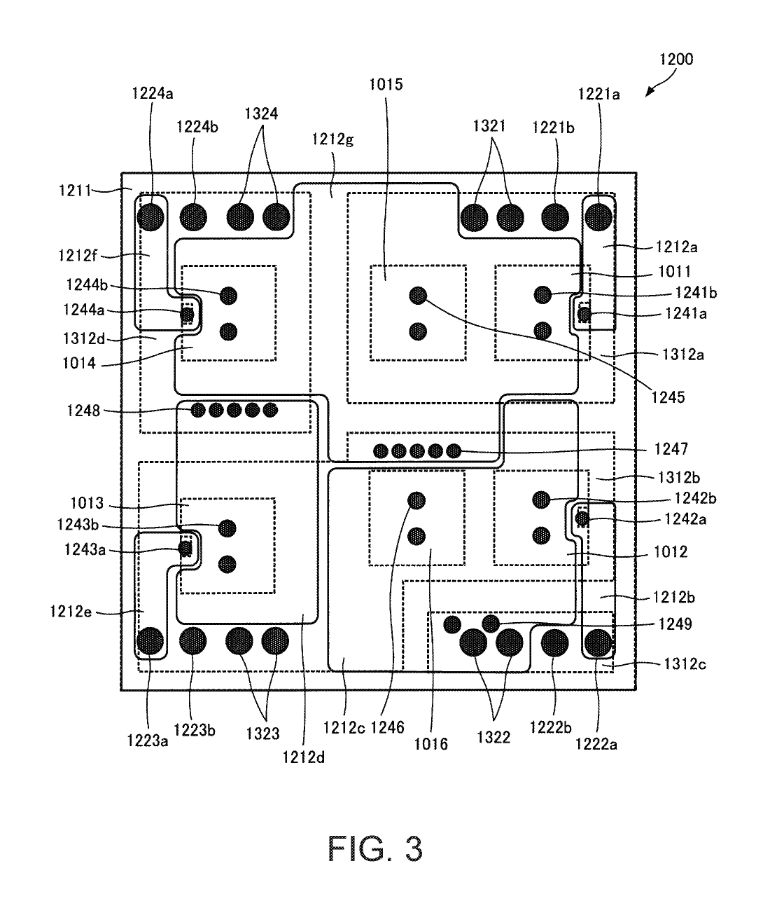

FIG. 3 is a top view of the printed circuit board of the semiconductor unit according to Embodiment 1.

FIG. 3 illustrates the front surface (top surface) of the printed circuit board 1200, and the dashed lines indicate the positioning of the multilayer substrate 1300 relative to the printed circuit board 1200.

As illustrated in FIG. 3, the printed circuit board 1200 includes the resin layer 1211 made from a flat, rectangle-shaped resin member, conductive circuit layers 1212a to 1212g arranged on the front surface of the resin layer 1211, and a circuit layer 1213 arranged on the rear surface of the resin layer 1211 (see FIG. 1B).

A plurality of conductive posts 1241a to 1244a, 1241b to 1244b, and 1245 to 1249 are formed in the printed circuit board 1200 and protrude from the front surface side and the rear surface side thereof. Furthermore, the plurality of conductive posts 1241a to 1244a, 1241b to 1244b, and 1245 to 1249 are electrically connected to the circuit layers 1212a to 1212g.

The conductive posts 1241a to 1244a are electrically connected to the gate electrodes of the semiconductor elements 1011 to 1014, respectively. The conductive posts 1241b to 1244b are electrically connected to the emitter electrodes of the semiconductor elements 1011 to 1014, respectively. The conductive posts 1245 and 1246 are electrically connected to the anode electrodes of the diodes 1015 and 1016, respectively. The conductive posts 1247 and 1248 are electrically connected to the circuit boards 1312b and 1312d of the multilayer substrate 1300, respectively. Moreover, the conductive post 1249 is electrically connected to the circuit board 1312c of the multilayer substrate 1300.

The control terminals 1221a to 1224a and 1221b to 1224b are arranged on the printed circuit board 1200. The control terminals 1221a to 1224a are electrically connected to the circuit layers 1212a, 1212b, 1212e, and 1212f, respectively. In other words, the control terminals 1221a to 1224a are electrically connected to the gate electrodes of the semiconductor elements 1011 to 1014, respectively, via the corresponding circuit layers and conductive posts.

The control terminals 1221b to 1224b are electrically connected to the circuit layer 1213 (not illustrated in the figure) arranged on the rear surface of the resin layer 1211. Furthermore, the control terminals 1221b to 1224b are electrically connected to the emitter electrodes of the semiconductor elements 1011 to 1014, respectively, via the corresponding circuit layers and conductive posts.

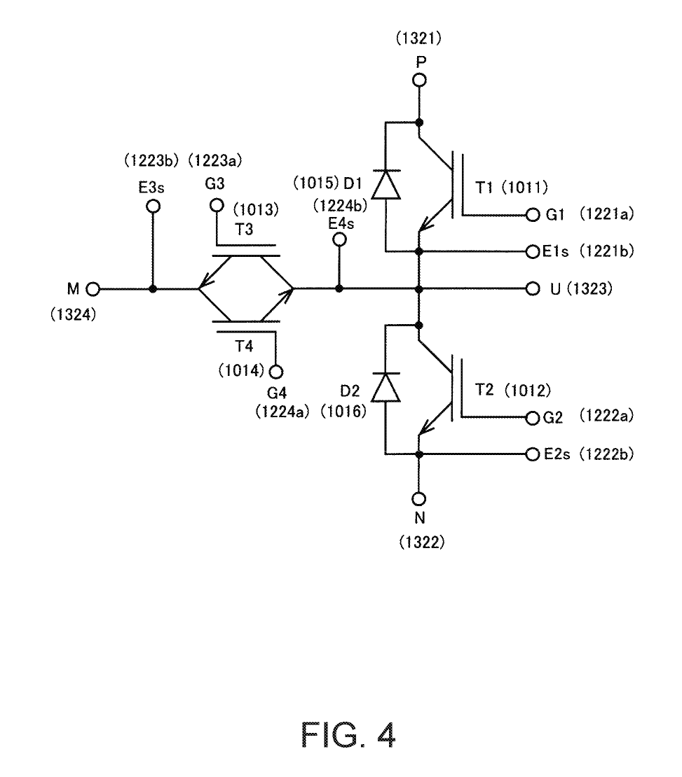

FIG. 4 is a circuit diagram illustrating a circuit configuration of the semiconductor unit according to Embodiment 1.

FIG. 4 illustrates a three-level inverter circuit formed inside the semiconductor unit 1000 by the multilayer substrate 1300; the semiconductor elements 1011 to 1014; the diodes 1015 and 1016; the printed circuit board 1200; and the conductive posts 1241a to 1244a, 1241b to 1244b, and 1245 to 1249.

The high voltage terminal of an external power source is connected to the main terminal 1321 (the P-terminal), and the low voltage terminal of the external power source is connected to the main terminal 1322 (the N-terminal). Moreover, the midpoint voltage terminal of the external power source is connected to the main terminal 1324 (the M-terminal) Furthermore, a load (not illustrated in the figure) is connected to the main terminal 1323 (the output terminal/the U-terminal) of the semiconductor unit 1000. The semiconductor unit 1000 therefore functions as a three-level inverter.

When a gate voltage is applied to the control terminal 1221a according to an external control signal, this gate voltage is applied to the gate electrode of the semiconductor element 1011, and the semiconductor element 1011 (T1) transitions from the OFF state (the non-conducting state) to the ON state (the conducting state).

Similarly, when a gate voltage is applied to the control terminal 1222a according to an external control signal, this gate voltage is applied to the gate electrode of the semiconductor element 1012, and the semiconductor element 1012 (T2) transitions from the OFF state to the ON state.

Likewise, when a gate voltage is applied to the control terminal 1223a according to an external control signal, this gate voltage is applied to the gate electrode of the semiconductor element 1013, and the semiconductor element 1013 (T3) transitions from the OFF state to the ON state.

Similarly, when a gate voltage is applied to the control terminal 1224a according to an external control signal, this gate voltage is applied to the gate electrode of the semiconductor element 1014, and the semiconductor element 1014 (T4) switches from the OFF state to the ON state.

In a three-level inverter, to make the polarity of the inverter output voltage positive, typically T1 and T3 are switched ON and OFF alternately, T4 is always left in the ON state, and T2 is always left in the OFF state. Conversely, to make the polarity of the inverter output voltage negative, T2 and T4 are switched ON and OFF alternately, T3 is always left in the ON state, and T1 is always left in the OFF state.

The input voltage from the external power source is applied to the collector electrode of the semiconductor element 1011 (T1) via the main terminal 1321 (the P-terminal). Furthermore, to make the polarity of the output voltage positive as described above, for example, an ON signal is applied to T1. In this case, the emitter electrode on the front surface of the semiconductor element 1011 outputs a current, and this current is the output current.

The output current from the emitter electrode of the semiconductor element 1011 (T1) is then output from the main terminal 1323 (the U-terminal).

Furthermore, the midpoint voltage from the external power source is applied to the collector electrode of the semiconductor element 1014 via the main terminal 1324 (the M-terminal). When the semiconductor element 1011 (T1) is switched to the OFF state, the output current is transferred to the semiconductor element 1014 (T4), which is in the ON state. The emitter electrode on the front surface of the semiconductor element 1014 then outputs a current.

The output current from the emitter electrode of the semiconductor element 1014 (T4) is then output from the main terminal 1323 (the U-terminal).

Furthermore, a load is connected to the collector electrode of the semiconductor element 1012 (T2) via the main terminal 1323 (the U-terminal). To make the polarity of the output voltage of the inverter negative, the semiconductor element 1012 (T2) is switched to the ON state, and the emitter electrode on the front surface of the semiconductor element 1012 outputs a current.

The output current from the emitter electrode of the semiconductor element 1012 (T2) is then output from the main terminal 1322 (the N-terminal).

Furthermore, a load is connected to the collector electrode of the semiconductor element 1013 (T3) via the main terminal 1323 (the U-terminal). When the semiconductor element 1012 (T2) is switched to the OFF state, the output current is transferred to the semiconductor element 1013 (T3), which is in the ON state.

The output current from the emitter electrode of the semiconductor element 1013 (T3) is then output from the main terminal 1324 (the M-terminal).

The semiconductor unit 1000 controls the operations described above appropriately in order to make it possible to convert DC power input from the external power source into AC power in a highly efficient manner.

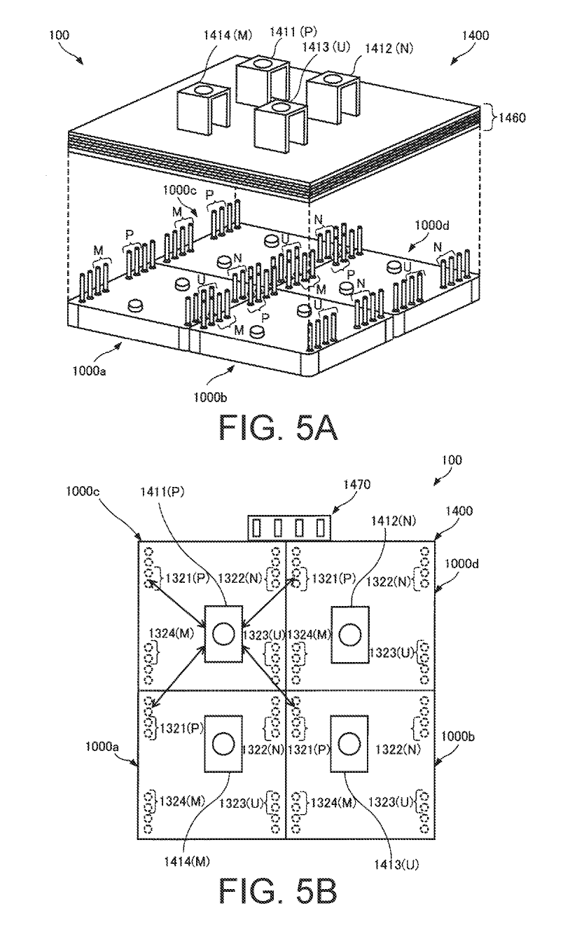

Next, a semiconductor device configured using a plurality of the semiconductor units 1000 in combination with a connecting unit 1400 will be described with reference to FIGS. 5A to 7B.

FIGS. 5A and 5B illustrate the semiconductor device according to Embodiment 1.

FIG. 5A is an exploded perspective view of the semiconductor device 100, and FIG. 5B is a top view of the semiconductor device 100. Note that in FIG. 5A, the external control terminals are not illustrated. Moreover, in FIG. 5B, the dashed lines indicate the positions of the main terminals of the semiconductor units 1000.

The semiconductor device 100 includes four semiconductor units 1000a to 1000d arranged in two rows and two columns in substantially the same plane. Furthermore, the semiconductor units 1000a to 1000d are electrically connected in parallel using the connecting unit 1400.

The connecting unit 1400 includes a printed circuit board 1460 and external terminals 1411 to 1414 that extend out of the printed circuit board 1460 in the same direction. The external terminals 1411 to 1414 function as the external terminals of the semiconductor device 100, which includes the three-level inverter circuits.

The printed circuit board 1460 internally includes a plurality of circuit layers that are electrically connected to the main terminals 1321 to 1324 of the semiconductor units 1000a to 1000d. This plurality of circuit layers is also electrically connected to the external terminals 1411 to 1414. In other words, the main terminals 1321 to 1324 are electrically connected to the corresponding external terminals 1411 to 1414 via the circuit layers of the printed circuit board 1460.

The printed circuit board 1460 also includes a plurality of control circuit layers that are electrically connected to the control terminals 1221a to 1224a and 1221b to 1224b of the semiconductor units 1000a to 1000d. Furthermore, the connecting unit 1400 includes an external control terminal 1470 that is electrically connected to these control circuit layers.

The external terminals 1411 to 1414 have a U-shaped cross section, for example. The external terminals 1411 to 1414 are arranged in two columns on top of the circuit layers and are arranged in the following order clockwise starting from the top left of FIG. 5B: P-terminal, N-terminal, U-terminal, and M-terminal. Similarly, in each of the semiconductor units 1000a to 1000d arranged as described above, the main terminals 1321 to 1324 are arranged in two columns and are arranged in the following order clockwise starting from the top left of FIG. 5B: P-terminal, N-terminal, U-terminal, and M-terminal. In other words, a geometrical arrangement of the main terminals 1321 to 1324, in a plan view, of each of the semiconductor units 1000a to 1000d relative to an overall plan-view shape of the semiconductor unit and a geometrical arrangement of the external terminals 1411 to 1414, in a plan view, of the connecting unit 1400 relative to an overall plan-view shape of the connecting unit have a substantial geometrical similarity with each other.

As illustrated in FIG. 5B, this makes it possible to arrange the external terminal 1411 (the P-terminal) within a prescribed distance of all of the main terminals 1321 (the P-terminals) of the semiconductor units 1000a to 1000d. Similarly, this makes it possible to arrange the external terminal 1412 (the N-terminal) within a prescribed distance of all of the main terminals 1322 (the N-terminals) of the semiconductor units 1000a to 1000d. Likewise, this makes it possible to arrange the external terminal 1413 (the U-terminal) within a prescribed distance of all of the main terminals 1323 (the U-terminals) of the semiconductor units 1000a to 1000d. Furthermore, this makes it possible to arrange the external terminal 1414 (the M-terminal) within a prescribed distance of all of the main terminals 1324 (the M-terminals) of the semiconductor units 1000a to 1000d.

Embodiment 1 makes it possible to make the lengths of the wires from the main terminals of the semiconductor units to the external terminals equal, thereby making it possible to reduce variation between the currents flowing through those wires. This makes it possible to make each of the semiconductor units have the same inductance and electrical resistance. This, in turn, makes it possible to make the semiconductor units exhibit uniform current loads and heat generation during operation, thereby making it possible to improve the reliability of the semiconductor device.

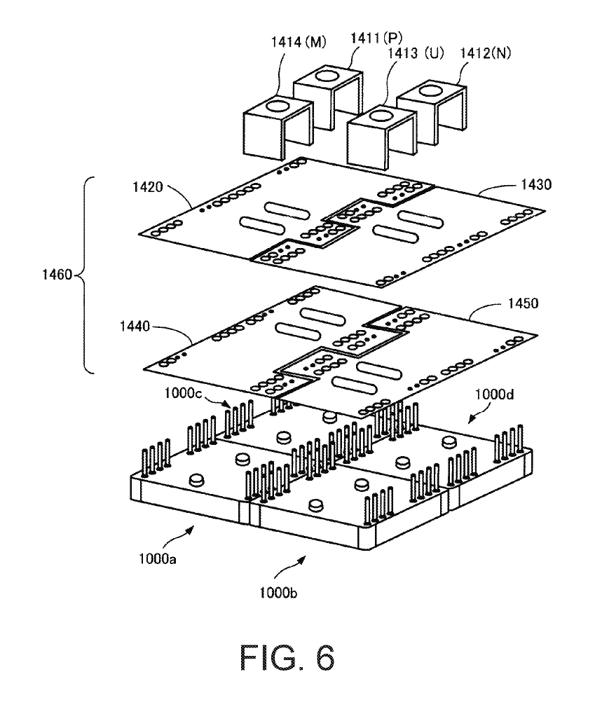

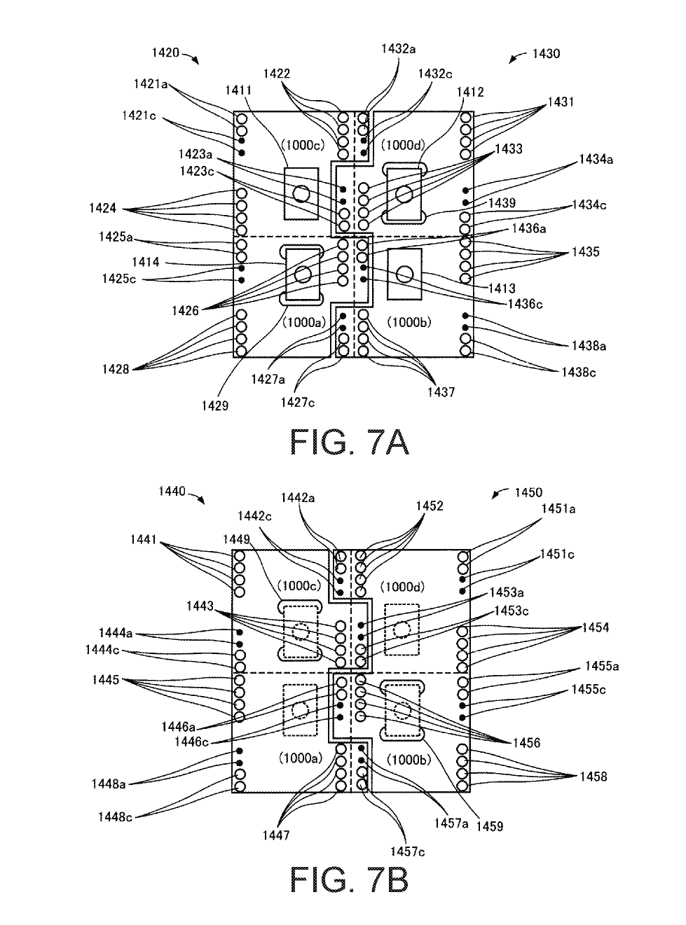

FIGS. 6 and 7A to 7B illustrate the details of the semiconductor unit according to Embodiment 1.

FIG. 7A is top view of circuit layers 1420 and 1430, and FIG. 7B is a top view of circuit layers 1440 and 1450. Furthermore, in FIGS. 7A and 7B, the reference characters 1000a to 1000d are used to indicate the regions of the circuit layers 1420 to 1450 that correspond to the semiconductor units 1000a to 1000d.

As illustrated in FIG. 6, the printed circuit board 1460 includes a pair of circuit layers 1420 and 1430 and a pair of circuit layers 1440 and 1450, and these two pairs of circuit layers are separated from one another by an insulating layer (not illustrated in the figure) layered therebetween. The external terminals 1411 to 1414 are arranged on top of the circuit layers 1420 and 1430. The printed circuit board 1460 also includes a separately formed gate terminal control circuit layer and a sense emitter terminal control circuit layer (neither of these layers are illustrated in the figure).

The main terminal 1321 (the P-terminal) of the semiconductor unit 1000c extends through a through-hole 1441 in the circuit layer 1440 and is connected to a connection point 1421c on the circuit layer 1420. The main terminal 1322 (the N-terminal) is connected to a connection point 1442c on the circuit layer 1450 and protrudes out from a through-hole 1422 in the circuit layer 1420. The main terminal 1323 (the U-terminal) protrudes out from a through-hole 1443 in the circuit layer 1440 and is connected to a connection point 1423a on the circuit layer 1430. The main terminal 1324 (the M-terminal) is connected to a connection point 1444a on the circuit layer 1440 and protrudes out from a through-hole 1424 in the circuit layer 1420.

The main terminal 1321 (the P-terminal) of the semiconductor unit 1000d protrudes out from a through-hole 1452 in the circuit layer 1450 and is connected to a connection point 1432c on the circuit layer 1420. The main terminal 1322 (the N-terminal) is connected to a connection point 1451c on the circuit layer 1450 and protrudes out from a through-hole 1431 in the circuit layer 1430. The main terminal 1323 (the U-terminal) protrudes out from a through-hole 1454 in the circuit layer 1450 and is connected to a connection point 1434a on the circuit layer 1430. The main terminal 1324 (the M-terminal) is connected to a connection point 1453a on the circuit layer 1440 and protrudes out from a through-hole 1433 in the circuit layer 1430.

The main terminal 1321 (the P-terminal) of the semiconductor unit 1000a protrudes out from a through-hole 1445 in the circuit layer 1440 and is connected to a connection point 1425c on the circuit layer 1420. The main terminal 1322 (the N-terminal) is connected to a connection point 1446c on the circuit layer 1450 and protrudes out from a through-hole 1426 in the circuit layer 1420. The main terminal 1323 (the U-terminal) protrudes out from a through-hole 1447 in the circuit layer 1440 and is connected to a connection point 1427a on the circuit layer 1430. The main terminal 1324 (the M-terminal) is connected to a connection point 1448a on the circuit layer 1440 and protrudes out from a through-hole 1428 in the circuit layer 1420.

The main terminal 1321 (the P-terminal) of the semiconductor unit 1000b protrudes out from a through-hole 1456 in the circuit layer 1450 and is connected to a connection point 1436c on the circuit layer 1420. The main terminal 1322 (the N-terminal) is connected to a connection point 1455c on the circuit layer 1450 and protrudes out from a through-hole 1435 in the circuit layer 1430. The main terminal 1323 (the U-terminal) protrudes out from a through-hole 1458 in the circuit layer 1450 and is connected to a connection point 1438a on the circuit layer 1430. The main terminal 1324 (the M-terminal) is connected to a connection point 1457a on the circuit layer 1440 and protrudes out from a through-hole 1437 in the circuit layer 1430.

Although the details of the configuration will not be described here, the control terminals 1221a to 1224a and 1221b to 1224b of the semiconductor units 1000a to 1000d protrude out from prescribed through-holes in the circuit layers 1420 to 1450 and are electrically connected to the corresponding control circuit layers.

The external terminal 1411 (the P-terminal) is electrically connected to the circuit layer 1420 and extends through a through-hole 1449 in the circuit layer 1440. The external terminal 1412 (the N-terminal) extends through a through-hole 1439 in the circuit layer 1430 and is electrically connected to the circuit layer 1450. The external terminal 1413 (the U-terminal) is electrically connected to the circuit layer 1430 and extends through a through-hole 1459 in the circuit layer 1450. The external terminal 1414 (the M-terminal) extends through a through-hole 1429 in the circuit layer 1420 and is electrically connected to the circuit layer 1440.

In the configuration of Embodiment 1 as described above, using the connecting unit 1400 makes it possible to electrically connect the plurality of semiconductor units 1000a to 1000d together in parallel.

In the semiconductor device 100, the high voltage terminal of the external power source is connected to the external terminal 1411 of the connecting unit 1400, and the low voltage terminal of the external power source is connected to the external terminal 1412 of the connecting unit 1400. Moreover, the midpoint voltage terminal of the external power source is connected to the external terminal 1414, and a load is connected to the external terminal 1413. The semiconductor device 100 therefore functions as a three-level inverter with a current rating four times greater than the current rating of each individual semiconductor unit 1000.

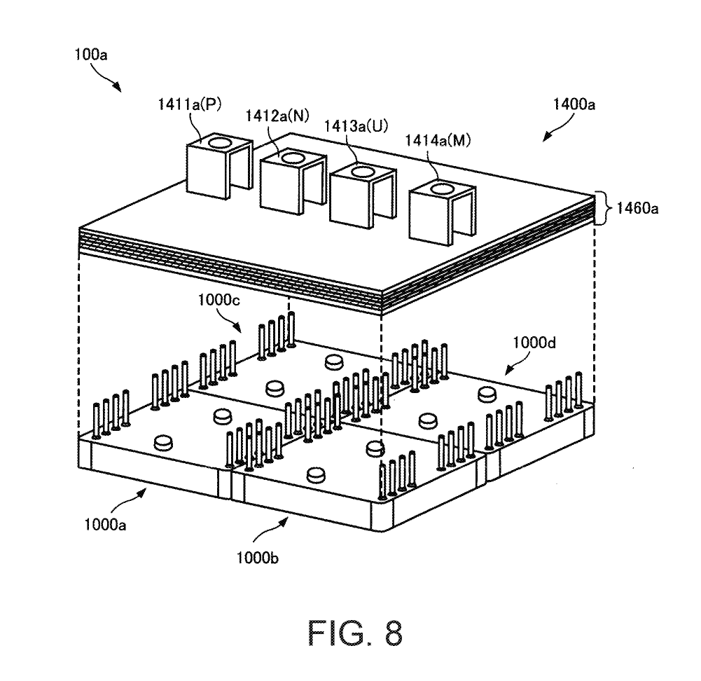

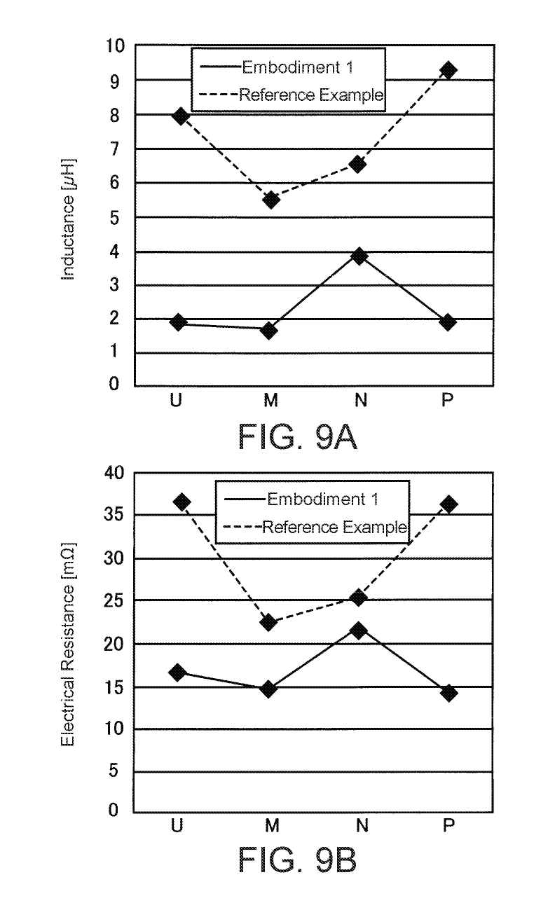

Next, the results of an evaluation of the inductance and resistance of wires in Embodiment 1 will be described with reference to FIGS. 8 and 9A to 9B.

FIG. 8 illustrates a reference example of a semiconductor device. FIGS. 9A and 9B include graphs showing the characteristics of the semiconductor device according to Embodiment 1.

In FIG. 9A, the horizontal axis represents the U-terminal, the M-terminal, the N-terminal, and the P-terminal, and the vertical axis shows the inductance (in μH) of each terminal. In FIG. 9B, the horizontal axis represents the U-terminal, the M-terminal, the N-terminal, and the P-terminal, and the vertical axis shows the electrical resistance (in mΩ) of each terminal.

The semiconductor device 100a illustrated in FIG. 8 was used for reference when evaluating the inductance and electrical resistance of the wires of the semiconductor device 100.

In the semiconductor device 100a, the main terminals of the semiconductor units 1000a to 1000d of Embodiment 1 are connected together in parallel using a connecting unit 1400a that is different from the connecting unit 1400 of Embodiment 1. In the connecting unit 1400a, external terminals 1411a to 1414a are arranged in a single column on top of the circuit layers and are arranged in the following order from left to right in FIG. 8: P-terminal, N-terminal, U-terminal, and M-terminal. In other words, the main terminals 1321 to 1324 of the semiconductor units 1000a to 1000d and the external terminals 1411a to 1414a of the connecting unit 1400a are arranged in different configurations. Furthermore, circuit layers of a printed circuit board 1460a of the connecting unit 1400a are configured appropriately according to the positions of the external terminals 1411a to 1414a.

A gate voltage with a frequency of 1 MHz was applied to the semiconductor devices 100 and 100a, and the inductance and electrical resistance of the wires in each semiconductor device were evaluated at each terminal.

As shown by the evaluation results in FIGS. 9A and 9B, the inductance and electrical resistance of each of the wires were lower in the semiconductor device 100 according to Embodiment 1 than in the semiconductor device 100a according to the reference example. Furthermore, the variation in inductance and electrical resistance between the wires of each terminal is also lower in the semiconductor device 100 according to Embodiment 1.

In the semiconductor device 100, a geometrical arrangement of the main terminals 1321 to 1324, in a plan view, of each of the semiconductor units 1000a to 1000d relative to an overall plan-view shape of the semiconductor unit and a geometrical arrangement of the external terminals 1411 to 1414, in a plan view, of the connecting unit 1400 relative to an overall plan-view shape of the connecting unit have a substantial geometrical similarity with each other. Therefore, the prescribed distances between the external terminals 1411 to 1414 and the main terminals 1321 to 1324 are uniform, and variation between the currents flowing between these terminals as well as variation in the heat generated due to those currents are reduced. This makes it possible to reduce increases in inductance and electrical resistance in the wires connected to each semiconductor unit due to differences in the distances between the external terminals 1411 to 1414 and the main terminals 1321 to 1324. This, in turn, makes high speed switching possible in the semiconductor device 100.

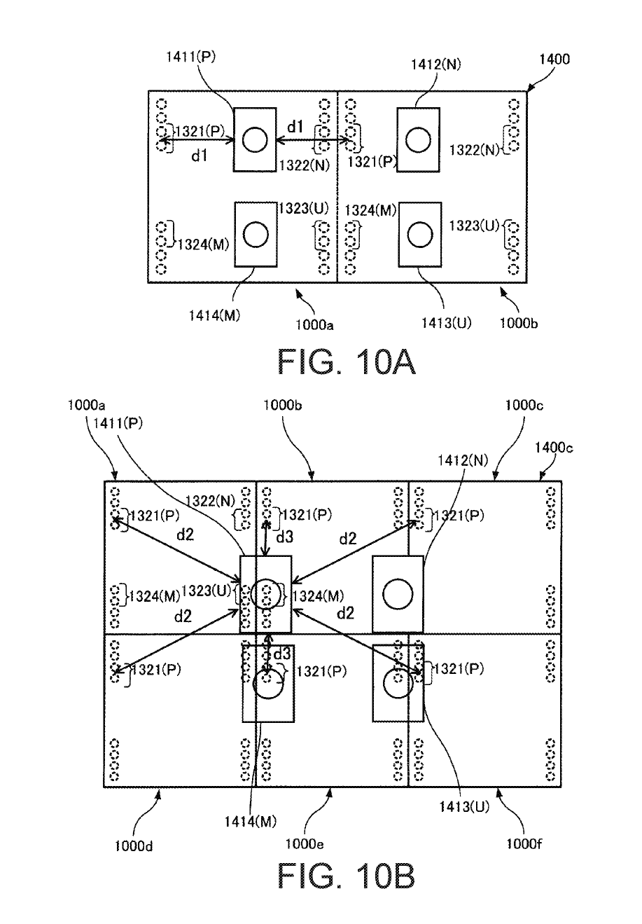

Embodiment 1 was described using an example in which the semiconductor units 1000a to 1000d are arranged in two rows and two columns. However, the arrangement of the plurality of semiconductor units 1000 is not particularly limited. Next, other arrangements for the semiconductor units 1000 will be described with reference to FIGS. 10A and 10B.

FIGS. 10 and 10B illustrate various ways of arranging a plurality of the semiconductor units according to Embodiment 1.

FIG. 10A illustrates a one row, two column arrangement of the semiconductor units 1000, and FIG. 10B illustrates a two row, three column arrangement of the semiconductor units 1000. Note that in FIGS. 10A and 10B, the external control terminals of the connecting units are not illustrated.

In FIG. 10A, two semiconductor units 1000a and 1000b are arranged in one row and two columns and are connected together in parallel using a connecting unit 1400b. Furthermore, in the connecting unit 1400b, a P-terminal, an N-terminal, a U-terminal, and an M-terminal are arranged in that order clockwise starting from the top left of FIG. 10A and are arranged in two columns. In other words, a geometrical arrangement of the main terminals 1321 to 1324, in a plan view, of each of the semiconductor units 1000a and 1000b relative to an overall plan-view shape of the semiconductor unit and a geometrical arrangement of the external terminals 1411 to 1414, in a plan view, of the connecting unit 1400b relative to an overall plan-view shape of the connecting unit have a substantial geometrical similarity with each other. This makes it possible to arrange the external terminals 1411 to 1414 within prescribed distances from the main terminals 1321 to 1324 of the semiconductor units 1000a and 1000b. For example, this makes it possible to arrange the external terminal 1411 at the same distance d1 from both of the main terminals 1321 (the P-terminals) of the semiconductor units 1000a and 1000b. This, in turn, makes it possible to reduce variation between the currents flowing between the external terminal 1411 and the main terminals 1321 of the semiconductor units 1000a and 1000b.

Furthermore, based on the above, the semiconductor units 1000 may be arranged in any one row, two or more column configuration as long as the external terminals 1411 to 1414 are arranged at the same distances from the main terminals 1321 to 1324 of the semiconductor units 1000 on both ends of the overall semiconductor unit 1000 arrangement. This makes it possible to reduce variation between the currents flowing between the external terminals 1411 to 1414 and the main terminals 1321 to 1324 of each of the semiconductor units 1000 in the overall arrangement.

In FIG. 10B, six semiconductor units 1000a to 1000f are arranged in two rows and three columns and are connected together in parallel using a connecting unit 1400c. Furthermore, in the connecting unit 1400c, a P-terminal, an N-terminal, a U-terminal, and an M-terminal are arranged in that order clockwise starting from the top left of FIG. 10B and are arranged in two columns. In other words, a geometrical arrangement of the main terminals 1321 to 1324, in a plan view, of each of the semiconductor units 1000a to 1000f relative to an overall plan-view shape of the semiconductor unit and a geometrical arrangement of the external terminals 1411 to 1414, in a plan view, of the connecting unit 1400c relative to an overall plan-view shape of the connecting unit have a substantial geometrical similarity with each other. This makes it possible to arrange the external terminals 1411 to 1414 within prescribed distances from the main terminals 1321 to 1324 of the semiconductor units 1000a to 1000f. For example, this makes it possible to arrange the external terminal 1411 at the same distance d2 from each of the main terminals 1321 (the P-terminals) of the semiconductor units 1000a, 1000c, 1000d, and 1000f. Moreover, this makes it possible to arrange the external terminal 1411 at the same distance d3 from both of the main terminals 1321 (the P-terminals) of the semiconductor units 1000b and 1000e. In other words, this makes it possible to arrange the external terminal 1411 at or within the distance d2 from each of the main terminals 1321 (the P-terminals) of the semiconductor units 1000a to 1000f. This, in turn, makes it possible to reduce variation between the currents flowing between the external terminal 1411 and the main terminals 1321 of the semiconductor units 1000a to 1000f.

Furthermore, based on the above, the semiconductor units 1000 may be arranged in any two or more row, two or more column configuration as long as the external terminals 1411 to 1414 are arranged at the same distances from the main terminals 1321 to 1324 of the semiconductor units 1000 at each of the four corners of the overall semiconductor unit 1000 arrangement. This makes it possible to reduce variation between the currents flowing between the external terminals 1411 to 1414 and the main terminals 1321 to 1324 of each of the semiconductor units 1000 in the overall arrangement.

### Embodiment 2

In Embodiment 2, a case in which semiconductor units that function as two-level inverter circuits are used will be described.

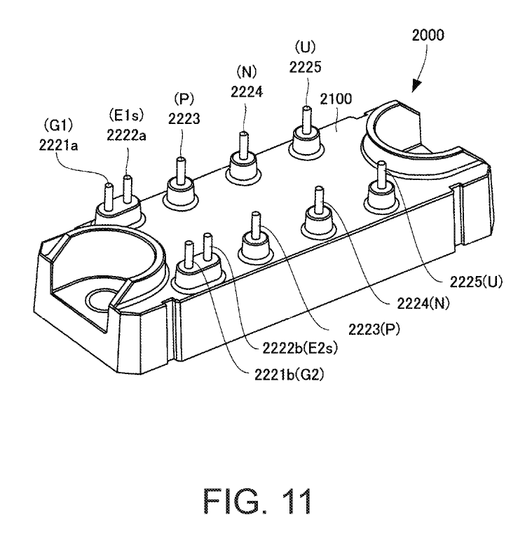

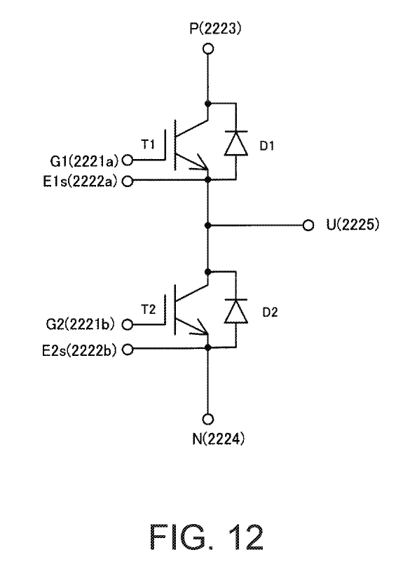

First, a semiconductor unit according to Embodiment 2 will be described with reference to FIGS. 11 and 12.

FIG. 11 is an exterior perspective view of the semiconductor unit according to Embodiment 2.

FIG. 12 is a circuit diagram illustrating a circuit configuration of the semiconductor unit according to Embodiment 2.

In the semiconductor unit 2000, IGBT semiconductor elements T1 and T2 and diodes D1 and D2 are arranged on a multilayer substrate (not illustrated in the figure) in order to form a two-level inverter circuit, which is then sealed using a resin 2100. As illustrated in FIG. 11, the semiconductor unit 2000 is substantially rectangular prism-shaped due to the resin 2100 and includes a main terminal 2223 (a P-terminal), a main terminal 2224 (an N-terminal) and a main terminal 2225 (a U-terminal), and all of these main terminals extend out in the same direction. In Embodiment 2, each of the main terminals 2223 to 2225 includes two leads. However, this is only to increase the amount of current that flows to the main terminals, and both leads of each main terminal have the same function. In other words, the main terminals 2223 to 2225 do not necessarily need to include two leads, and each main terminal may include only a single lead. Therefore, the following description of the semiconductor unit 2000 according to the present embodiment assumes that each of the main terminals 2223 to 2225 is a single-lead terminal.

The semiconductor unit 2000 also includes a control terminal 2221a (a gate terminal G1), a control terminal 2221b (a gate terminal G2), a control terminal 2222a (a sense emitter terminal E1s), and a control terminal 2222b (a sense emitter terminal E2s).

As illustrated in FIG. 11, the semiconductor element T1 and the diode D1 of the semiconductor unit 2000 are connected in anti-parallel and form the upper arm of the inverter. Similarly, the semiconductor element T2 and the diode D2 are connected in anti-parallel and form the lower arm of the inverter.

The high voltage terminal of an external power source is connected to the main terminal 2223 (the P-terminal), and the low voltage terminal of the external power source is connected to the main terminal 2224 (the N-terminal). Furthermore, a load (not illustrated in the figure) is connected to the main terminal 2225 (the output terminal/the U-terminal) of the semiconductor unit 2000. The semiconductor unit 2000 therefore functions as a two-level inverter.

In a two-level inverter circuit, to make the polarity of the inverter output voltage positive, typically T1 is always left in the ON state, and T2 is always left in the OFF state. Conversely, to make the polarity of the inverter output voltage negative, T2 is always left in the ON state, and T1 is always left in the OFF state.

The input voltage from the external power source is applied to the collector electrode of the semiconductor element T1 via the main terminal 2223 (the P-terminal). Furthermore, to make the polarity of the output voltage positive as described above, for example, an ON signal is applied to T1. In this case, the emitter electrode of the semiconductor element T1 outputs a current, and this current is the output current.

The output current from the emitter electrode of the semiconductor element T1 is then output from the main terminal 2225 (the U-terminal).

Furthermore, a load is connected to the collector electrode of the semiconductor element T2 via the main terminal 2225 (the U-terminal). To make the polarity of the output voltage of the inverter negative, the semiconductor element T2 is switched to the ON state, and the emitter electrode of the semiconductor element T2 outputs a current.

The output current from the emitter electrode of the semiconductor element T2 is then output from the main terminal 2224 (the N-terminal).

The semiconductor unit 2000 controls the operations described above appropriately in order to make it possible to convert DC power input from the external power source into AC power in a highly efficient manner.

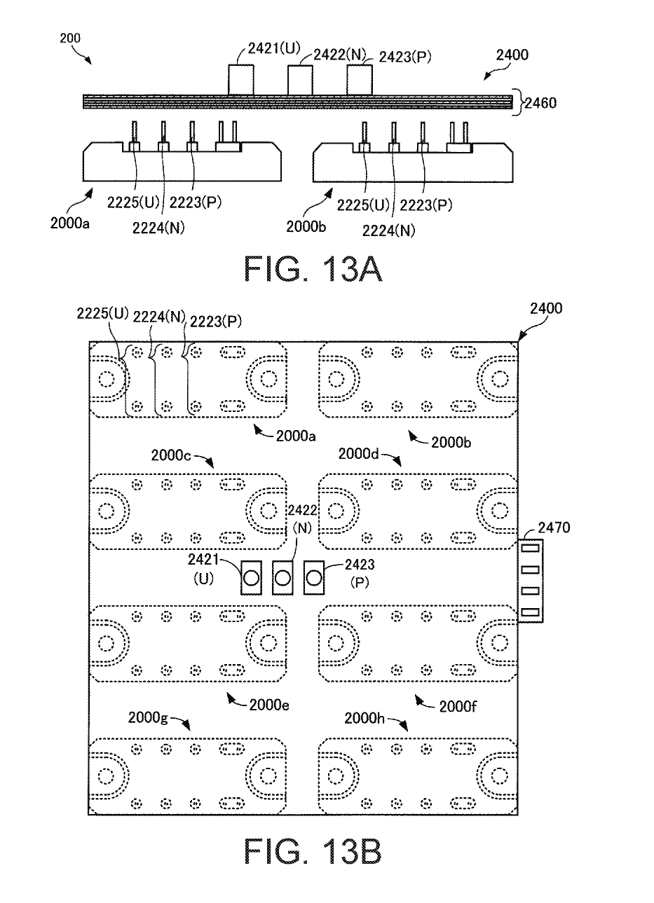

Next, a semiconductor device 200 configured using a plurality of the semiconductor units 2000 will be described with reference to FIGS. 13A to 16.

FIGS. 13A and 13B illustrate the semiconductor device according to Embodiment 2.

FIG. 13A is an exploded side view of the semiconductor device 200, and FIG. 13B is a top view of the semiconductor device 200. Note that in FIG. 13A, the external control terminals are not illustrated. Moreover, in FIG. 13B and FIGS. 14 to 16, the dashed lines indicate the positions of the semiconductor units 2000. Furthermore, in FIG. 13B and FIGS. 14 to 16, only the main terminals of the semiconductor unit 2000a are labeled with reference characters. However, the same reference characters also apply to the main terminals of the other semiconductor units 2000b to 2000h.

The semiconductor device 200 includes eight semiconductor units 2000a to 2000h arranged in four rows and two columns in substantially the same plane. Furthermore, the semiconductor units 2000a to 2000h are electrically connected in parallel using a connecting unit 2400.

The connecting unit 2400 includes a printed circuit board 2460 and external terminals 2421 to 2423 that extend out of the printed circuit board 2460 in the same direction.

The printed circuit board 2460 internally includes a plurality of circuit layers that are electrically connected to the main terminals 2223 to 2225 of the semiconductor units 2000a to 2000h arranged as described above. This plurality of circuit layers is also electrically connected to the external terminals 2421 to 2423. In other words, the main terminals 2223 to 2225 are electrically connected to the corresponding external terminals 2421 to 2423 via the circuit layers of the printed circuit board 2460.

The printed circuit board 2460 also includes a plurality of control circuit layers that are electrically connected to the control terminals 2221a, 2221b, 2222a, and 2222b of the semiconductor units 2000a to 2000h. Furthermore, the connecting unit 2400 includes an external control terminal 2470 that is electrically connected to these control circuit layers.

Like the external terminals 1411 to 1414 in Embodiment 1, the external terminals 2421 to 2423 have a U-shaped cross section. The external terminals 2421 to 2423 are arranged in one row on top of the circuit layers and are arranged in the following order from left to right in FIG. 13B: U-terminal, N-terminal, and P-terminal. Similarly, in each of the semiconductor units 2000a to 2000h arranged as described above, the main terminals 2223 to 2225 are arranged in one row and are arranged in the following order from left to right in FIG. 13B: U-terminal, N-terminal, and P-terminal. In other words, a geometrical arrangement of the main terminals 2223 to 2225, in a plan view, of each of the semiconductor units 2000a to 2000h relative to an overall plan-view shape of the semiconductor unit and a geometrical arrangement of the external terminals 2421 to 2423, in a plan view, of the connecting unit 2400 relative to an overall plan-view shape of the connecting unit have a substantial geometrical similarity with each other.

As illustrated in FIG. 13B, this makes it possible to arrange the external terminal 2421 (the U-terminal) within a prescribed distance of all of the main terminals 2225 (the U-terminals) of the semiconductor units 2000a to 2000h. Similarly, this makes it possible to arrange the external terminal 2422 (the N-terminal) within a prescribed distance of all of the main terminals 2224 (the N-terminals) of the semiconductor units 2000a to 2000h. Likewise, this makes it possible to arrange the external terminal 2423 (the P-terminal) within a prescribed distance of all of the main terminals 2223 (the P-terminals) of the semiconductor units 2000a to 2000h.

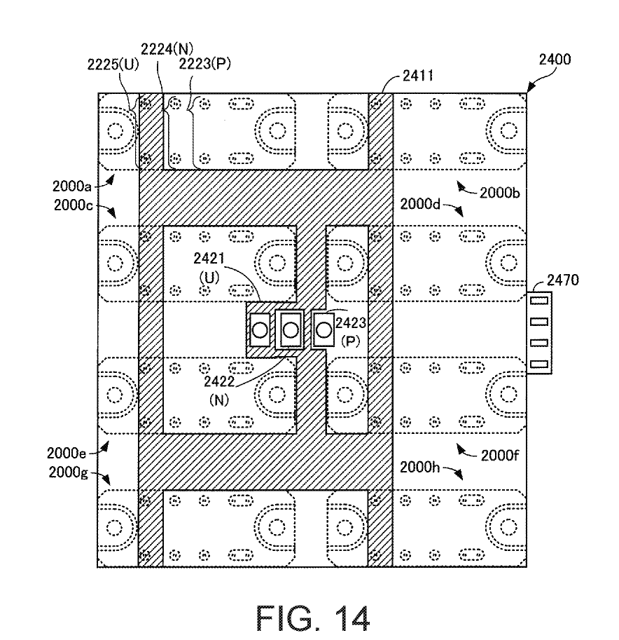

FIGS. 14 to 16 are top views of the circuit layers of the connecting unit of the semiconductor device according to Embodiment 2.

As illustrated in FIG. 14, a circuit layer 2411 electrically connects the main terminals 2225 (the U-terminals) of the semiconductor units 2000a to 2000h to the external terminal 2421 (the U-terminal).

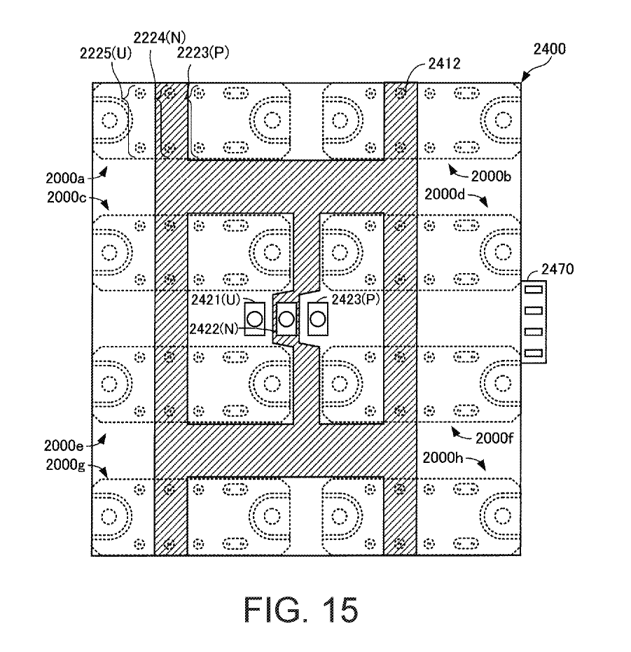

As illustrated in FIG. 15, a circuit layer 2412 electrically connects the main terminals 2224 (the N-terminals) of the semiconductor units 2000a to 2000h to the external terminal 2422 (the N-terminal).

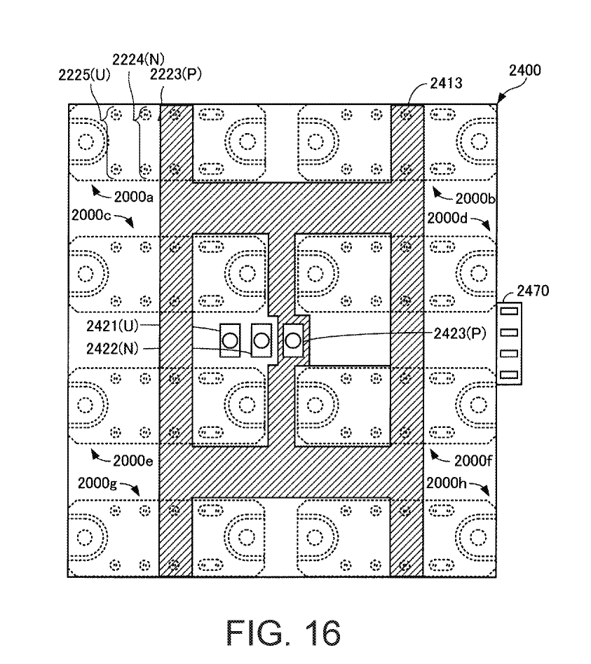

As illustrated in FIG. 16, a circuit layer 2413 electrically connects the main terminals 2223 (the P-terminals) of the semiconductor units 2000a to 2000h to the external terminal 2423 (the P-terminal).

In the printed circuit board 2460, the circuit layers 2411, 2412, and 2413 are separated from one another by insulating layers (not illustrated in the figure) layered therebetween. In the configuration of the present embodiment as described above, using the connecting unit 2400 makes it possible to electrically connect the plurality of semiconductor units 2000a to 2000h together in parallel.

In the semiconductor device 200 according to Embodiment 2, the high voltage terminal of the external power source is connected to the external terminal 2423 of the connecting unit 2400, and the low voltage terminal of the external power source is connected to the external terminal 2422 of the connecting unit 1400. Moreover, a load is connected to the external terminal 2421 of the connecting unit 2400. The semiconductor device 200 therefore functions as a two-level inverter with a current rating eight times greater than the current rating of each individual semiconductor unit 2000.

In the semiconductor device 200, a geometrical arrangement of the main terminals 2223 to 2225, in a plan view, of the semiconductor units 2000a to 2000h relative to an overall plan-view shape of the semiconductor unit and a geometrical arrangement of the external terminals 2421 to 2423, in a plan view, of the connecting unit 2400 relative to an overall plan-view shape of the connecting unit have a substantial geometrical similarity with each other. Therefore, the prescribed distances between the external terminals 2421 to 2423 and the main terminals 2223 to 2225 are uniform, and variation between the currents flowing between these terminals as well as variation in the heat generated due to those currents are reduced. This makes it possible to reduce increases in inductance and electrical resistance in the wires connected to each semiconductor unit between the external terminals 2421 to 2423 and the main terminals 2223 to 2225. This, in turn, makes high speed switching possible in the semiconductor device 200.

It will be apparent to those skilled in the art that various modifications and variations can be made in the present invention without departing from the spirit or scope of the invention. Thus, it is intended that the present invention cover modifications and variations that come within the scope of the appended claims and their equivalents. In particular, it is explicitly contemplated that any part or whole of any two or more of the embodiments and their modifications described above can be combined and regarded within the scope of the present invention.

What is claimed is:

1. A semiconductor device, comprising:
a plurality of semiconductor units each including a semiconductor element and a plurality of main terminals that are electrically connected to the semiconductor element, the plurality of semiconductor units being arranged in a same plane with a same orientation in a plan view; and
a connecting unit that electrically connects in parallel the semiconductor units arranged in substantially the same plane, the connecting unit having a plurality of external terminals that are respectively connected to the main terminals of each of the semiconductor units,
wherein a geometrical arrangement of the main terminals, in a plan view, of each of the semiconductor units relative to an overall plan-view shape of the semiconductor unit and a geometrical arrangement of the external terminals, in a plan view, of the connecting unit relative to an overall plan-view shape of the connecting unit have a substantial geometrical similarity with each other.

2. The semiconductor device according to claim 1,
wherein each semiconductor unit includes four main terminals,
wherein the connecting unit includes four external terminals,
wherein the four main terminals of each semiconductor unit are arranged in two columns, and
wherein the four external terminals of the connecting unit are arranged in two columns.

3. The semiconductor device according to claim 1,
wherein each semiconductor unit includes three main terminals,
wherein the connecting unit includes three external terminals,
wherein the three main terminals of each semiconductor unit are arranged in one column, and
wherein the three external terminals of the connecting unit are arranged in one column.

4. The semiconductor device according to claim 1,
wherein the connecting unit further includes a plurality of circuit layers, and
wherein the main terminals are electrically connected to the corresponding external terminals via the circuit layers.

5. The semiconductor device according to claim 1,
wherein the semiconductor units are arranged in one column, and
wherein each of the external terminals is arranged so as to be at a same distance to the corresponding main terminals on the semiconductor units that are arranged at respective ends of said one column.

6. The semiconductor device according to claim 1,
wherein the semiconductor units are arranged both horizontally and vertically with at least two semiconductor units in each direction, thereby forming a rectangular arrangement in a plan view, and
wherein each of the external terminals is arranged so as to be at a same distance to the corresponding main terminals on the semiconductor units that are located at respective four corners of the rectangular arrangement.

7. The semiconductor device according to claim 1, wherein each of the semiconductor units constitutes a three-level inverter circuit.

8. The semiconductor device according to claim 1, wherein each of the semiconductor units constitutes a two-level inverter circuit.

9. The semiconductor device according to claim 1, wherein each of the semiconductor units constitutes a three-level inverter circuit in which four external terminals are arranged in two columns.
